(19) United States
(12) Patent Application Publication
(10) Pub. No.: US 2020/0032408 A1
(43) Pub. Date: Jan. 30, 2020

(54) SYSTEM AND METHOD FOR MEASURING ANODE CURRENT OF ALUMINUM ELECTROLYTIC CELL

(71) Applicant: NORTH CHINA UNIVERSITY OF TECHNOLOGY, Beijing (CN)

(72) Inventors: Jun TIE, Beijing (CN); Rentao ZHAO, Beijing (CN); Zhifang ZHANG, Beijing (CN); Wentang ZHENG, Beijing (CN)

(73) Assignee: NORTH CHINA UNIVERSITY OF TECHNOLOGY, Beijing (CN)

(21) Appl. No.: 16/510,284

(22) Filed: Jul. 12, 2019

(30) Foreign Application Priority Data
Jul. 25, 2018 (CN) 201810823925.4

(51) Int. Cl. C25C 3/12; H01M 4/66; G01R 19/00

(52) U.S. Cl. CPC C25C 3/12; G01R 19/0092; H01M 4/66

(57) ABSTRACT

The present invention discloses a system and method for measuring an anode current of an aluminum electrolytic cell. The system includes a plurality of electrolytic cell units, where the electrolytic cell units each include: a column bus, two horizontal buses, m anodes, m anode rods, one or a pair of crossover buses, and a plurality of optical fiber current sensors. When one side of the anode rod is adjacent to another anode rod, the horizontal bus between the two anode rods is provided with one of the optical fiber current sensors; and when any side of the anode rod is adjacent to the column bus or the crossover bus, the horizontal bus between the anode rod and the column bus or the crossover bus is provided with one of the optical fiber current sensors. In the present invention, optical fiber current sensors are mounted between two adjacent anode rods and between the anode rod and the column bus or the crossover bus for current measurement, the current of each anode can be measured accurately, and the measurement precision is accurate to be within 1%.

This application claims priority to Chinese application number 201810823925.4, filed Jul. 25, 2018 with a title of SYSTEM AND METHOD FOR MEASURING ANODE CURRENT OF ALUMINUM ELECTROLYTIC CELL. The above-mentioned patent application is incorporated herein by reference in its entirety.

### TECHNICAL FIELD

The present invention relates to the technical field of current measurement, and in particular to a system and method for measuring an anode current of an aluminum electrolytic cell.

### BACKGROUND

As the capacity of an electrolytic cell increases significantly, the size of the electrolytic cell increases, and the number of anodes increases. Currently, the number of anodes in a largest electrolytic cell is close to 60. An electrolytic cell control system determines the change in pseudo-resistance of electrolyte based on the anode current, thereby controlling the thermal balance and the cell stability. Especially in the electrolytic cell, the magnitude of the anode current passing through each anode directly determines the amount of alumina of an anode region that participates in a reaction, namely the amount of alumina consumed. Therefore, how to accurately measure the anode current has become a top priority in the field.

At present, independent anode current measurement is performed mainly by adopting two methods: an equidistant voltage drop method and a Hall magnetic induction measurement method. The former is adopted for estimation based on the voltage drop generated when the current passes through a horizontal bus or an anode rod; the horizontal bus and the anode rod have larger geometrical dimensions, the current distribution in the cross section has uncertainty and non-uniformity and there is a difference in conductor temperature, so that only the trend of the change can be measured and it is difficult to obtain an accurate current; and the latter makes a very complex background magnetic field formed due to the staggered arrangement of conductors on the electrolytic cell, also making it difficult to measure the accurate current.

### SUMMARY

An objective of the present invention is to provide a system and method for measuring an anode current of an aluminum electrolytic cell, to accurately measure a current of each anode.

To achieve the above purpose, the present invention provides a system for measuring an anode current of an aluminum electrolytic cell, including a plurality of electrolytic cell units;

where the electrolytic cell units each include: a column bus, two horizontal buses, m anodes, m anode rods, one or a pair of crossover buses, and a plurality of optical fiber current sensors;

the m anode rods and the m anodes are divided into two rows A and B, one end of each of the anode rods of each row is respectively in lap joint with the horizontal bus, the other end of each of the anode rods of each row is respectively connected to the anode of each row, and each of the anodes is in one-to-one correspondence with the anode rod; the crossover buses are disposed on one or two sides of a feeding port, the two horizontal buses are connected through the crossover buses, and one end of the column bus is connected to the first horizontal bus;

when one side of the anode rod is adjacent to another anode rod, the horizontal bus between the two anode rods is provided with one of the optical fiber current sensors;

when any side of the anode rod is adjacent to the column bus or the crossover bus, the horizontal bus between the anode rod and the column bus or the crossover bus is provided with one of the optical fiber current sensors; and

when any side of the anode rod is neither adjacent to the anode rod nor adjacent to the column bus or the crossover bus, the horizontal bus on this side does not need to be provided with the optical fiber current sensor.

Optionally, the system further includes:

an optical fiber protecting tube, configured to, through a polarization maintaining optical fiber concentrated in the optical fiber protecting tube, transmit current information detected by the optical fiber current sensors to a measuring box for analysis and processing.

The present invention further provides a method for measuring an anode current of an aluminum electrolytic cell, where the method is applied to the above system, and the method includes:

determining a j-th anode of an i-th row where a current is to be detected, and a j-th anode rod of an i-th row corresponding to the j-th anode of the i-th row; where i is equal to A or B, and j is a positive integer which ranges from 2 to m/2;

determining whether column buses or crossover buses are present at both ends of the j-th anode rod of the i-th row, to obtain a first determining result;

if the first determining result indicates that the column buses or the crossover buses are present, determining that the current passing through the j-th anode of the i-th row is I_{j,r}ⁱ, I_{j,r}ⁱ+I_{j-1,j}ⁱ or I_{j,r}ⁱ+I_{j,j+1}ⁱ; where I_{j,r}ⁱ is a current detected by an optical fiber current sensor between the column bus or the crossover bus and the j-th anode rod of the i-th row, I_{j-1,j}ⁱ is a current detected by an optical fiber current sensor between a (j−1)-th anode rod of the i-th row and the j-th anode rod of the i-th row; and I_{j,j+1}ⁱ is a current detected by an optical fiber current sensor between the j-th anode rod of the i-th row and a (j+1)-th anode rod of the i-th row;

if the first determining result indicates that the column buses or the crossover buses are not present, determining whether anode rods are present at both ends of the j-th anode rod of the i-th row, to obtain a second determining result;

if the second determining result indicates that the anode rods are present, determining that the current passing through the j-th anode of the i-th row is I_{j-1,j}ⁱ+I_{j,j+1}ⁱ; if the second determining result indicates that only one anode rod is present, determining that the current passing through the j-th anode of the i-th row is I_{j-1,j}ⁱ or I_{j,j+1}ⁱ;

Optionally, the determining, if the first determining result indicates that the column buses or the crossover buses are present, that the current passing through the j-th anode of the i-th row is I_{j,r}ⁱ, I_{j,r}ⁱ+I_{j-1,j}ⁱ or I_{j,r}ⁱ+I_{j,j+1}ⁱ specifically includes:

if the first determining result indicates that the column buses or the crossover buses are present, determining whether an anode rod is present at the other end of the j-th anode rod of the i-th row, to obtain a third determining result;

if the third determining result indicates that the anode rod is not present at the other end of the j-th anode rod of the i-th row, determining that the current passing through the j-th anode of the i-th row is I_{j,r}ⁱ;

if the third determining result indicates that the anode rod is present at the other end of the j-th anode rod of the i-th row, determining whether the number thereof is the (j−1)-th of the i-th row, to obtain a fourth determining result;

if the fourth determining result indicates that the number of the anode rod at the other end of the j-th anode rod of the i-th row is the (j−1)-th of the i-th row, determining that the current passing through the j-th anode of the i-th row is I_{j,r}ⁱ+I_{j-1,j}ⁱ; and

if the fourth determining result indicates that the number of the anode rod at the other end of the j-th anode rod of the i-th row is not the (j−1)-th of the i-th row, determining that the current passing through the j-th anode of the i-th row is I_{j,r}ⁱ+I_{j,j+1}ⁱ.

Optionally, the determining, if the second determining result indicates that only one anode rod is present, that the current passing through the j-th anode of the i-th row is I_{j-1,j}ⁱ or I_{j,j+1}ⁱ specifically includes:

if the second determining result indicates that only one anode rod is present, determining whether the number of the anode rod is the (j−1)-th of the i-th row, to obtain a fifth determining result;

if the fifth determining result indicates that the number of the anode rod is the (j−1)-th of the i-th row, determining that the current passing through the j-th anode of the i-th row is I_{j-1,j}ⁱ; and if the fifth determining result indicates that the number of the anode rod is not the (j−1)-th of the i-th row, determining that the current passing through the j-th anode of the i-th row is I_{j,j+1}ⁱ.

Optionally, for the j-th anode rod of the i-th row, a current passing in the direction towards the anode rod is positive, and a current in the direction away from the anode rod is negative.

According to specific embodiments provided in the present invention, the present invention discloses the following technical effects:

In the present invention, optical fiber current sensors are mounted between two adjacent anode rods and between the anode rod and a column bus or a crossover bus for current measurement, the current of each anode can be measured accurately, and the measurement precision is accurate to be within 1%; the regional alumina feeding amount can be added as needed, and an anode state of the electrolytic cell is diagnosed, thereby achieving stable and efficient production of the electrolytic cell, significantly improving the current efficiency, reducing the energy consumption, and achieving further energy saving and emission reduction of the aluminum electrolytic cell.

### BRIEF DESCRIPTION OF THE DRAWINGS

To describe the technical solutions in the embodiments of the present invention or in the prior art more clearly, the following briefly introduces the accompanying drawings required for describing the embodiments. Apparently, the accompanying drawings in the following description show merely some embodiments of the present invention, and a person of ordinary skill in the art may still derive other drawings from these accompanying drawings without creative efforts.

FIG. 1 is a structural view of an electrolytic cell unit according to an embodiment of the present invention; and

FIG. 2 is a flow chart of a method for measuring an anode current of an aluminum electrolytic cell according to an embodiment of the present invention.

1. Column bus, 2. anode, 3. anode rod, 4. horizontal bus, 5. optical fiber current sensor, 6. crossover bus, 7. optical fiber protecting tube.

### DETAILED DESCRIPTION

The following clearly and completely describes the technical solutions in the embodiments of the present invention with reference to the accompanying drawings in the embodiments of the present invention. Apparently, the described embodiments are merely a part rather than all of the embodiments of the present invention. All other embodiments obtained by a person of ordinary skill in the art based on the embodiments of the present invention without creative efforts shall fall within the protection scope of the present invention.

An objective of the present invention is to provide a system and method for measuring an anode current of an aluminum electrolytic cell, to accurately measure a current of each anode.

To make the foregoing objective, features, and advantages of the present invention clearer and more comprehensible, the present invention is further described in detail below with reference to the accompanying drawings and specific embodiments.

The present invention provides a system for measuring an anode current of an aluminum electrolytic cell. The system includes a plurality of electrolytic cell units;

the electrolytic cell units each include: a column bus 1, two horizontal buses 4, m anodes 2, m anode rods 3, one or a pair of crossover buses 6, and a plurality of optical fiber current sensors 5;

the m anode rods 3 and the m anodes 2 are divided into two rows A and B, one end of each of the anode rods 3 of each row is respectively in lap joint with the horizontal bus 4, the other end of each of the anode rods 3 of each row is respectively connected to the anode 2 of each row, and each of the anodes 2 is in one-to-one correspondence with the anode rod 3; the crossover buses 6 are disposed on one or two sides of a feeding port, the two horizontal buses 4 are connected through the crossover buses 6, and one end of the column bus 1 is connected to the first horizontal bus 4; a current is transmitted to each of the horizontal buses 4 by the column bus 1 and the crossover buses, and then the current is transmitted via each of the horizontal bus 4 to the corresponding anode 2 through each of the anode rods 3 in lap joint with the horizontal buses 4.

when one side of the anode rod 3 is adjacent to another anode rod 3, the horizontal bus 4 between the two anode rods 3 is provided with one of the optical fiber current sensors 5;

when any side of the anode rod 3 is adjacent to the column bus 1 or the crossover bus 6, the horizontal bus 4 between the anode rod 3 and the column bus 1 or the crossover bus 6 is provided with one of the optical fiber current sensors 5;

when any side of the anode rod 3 is neither adjacent to the anode rod 3 nor adjacent to the column bus 1 or the crossover bus 6, the horizontal bus 4 on this side does not need to be provided with the optical fiber current sensor 5.

As an embodiment, the system of the present invention further includes:

an optical fiber protecting tube, configured to, through a polarization maintaining optical fiber concentrated in the optical fiber protecting tube, transmit current information detected by the optical fiber current sensors 5 to a measuring box for analysis and processing.

As an embodiment, the present invention divides the m anode rods 3 and the m anodes 2 into two rows A and B.

As an embodiment, in the present invention, for the j-th anode rod 3 of the i-th row, a current passing in the direction towards the anode rod 3 is positive, and a current in the direction away from the anode rod 3 is negative.

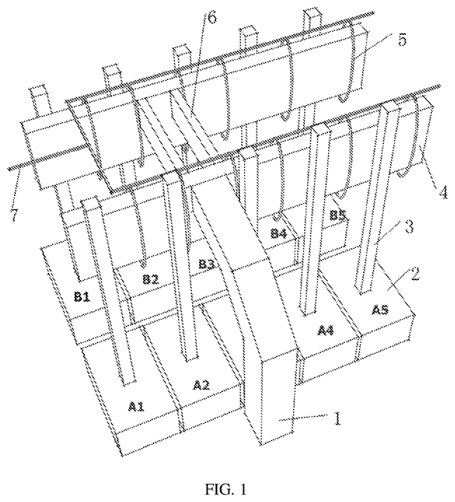

In order to better understand the technical solutions in the present invention, the present invention provides a specific embodiment. Specifically, as shown in FIG. 1, the electrolytic cell units of the present invention each include: a column bus 1, two horizontal buses 4, ten anodes 2, ten anode rods 3, a pair of crossover buses 6, and twelve optical fiber current sensors 5;

the ten anode rods 3 and the ten anodes 2 are divided into two rows A and B. The first anode 2 in the first row is denoted by A1, the first anode 2 in the second row is denoted by B1, and other anodes can be denoted in a similar way, which is not discussed herein one by one. One end of each of the anode rods 3 of each row is respectively in lap joint with the horizontal bus 4, the other end of each of the anode rods 3 of each row is respectively connected to the anode 2 of each row, and each of the anodes 2 is in one-to-one correspondence with the anode rod 3; the crossover buses 6 are disposed on both sides of a feeding port respectively, the two horizontal buses 4 are connected through the crossover buses 6, and one end of the column bus 1 is connected to the first horizontal bus 4. A current is transmitted by the column bus 1 to the horizontal bus 4 connected with the column bus 1, and is transmitted to the horizontal bus 4 on the side B through the crossover bus 6, and then the current is transmitted via the horizontal bus 4 to the corresponding anode 2 through the anode rod 3 in lap joint with the horizontal bus 4.

The optical fiber current sensor 5 effectively overcomes a background magnetic field and contact interference by utilizing the Faraday magneto-optical effect principle in which light can be deflected in a magnetic field and by utilizing a closed-loop optical path method, and thus the measurement accuracy is high. In addition, the optical fiber current sensor 5 transmits an optical signal, and a conductive medium is an optical fiber, which is naturally electrically insulating, safe, reliable, good in flexibility and easy to install.

In view of the frequent replacement operation on the anode 2, in the present invention, optical fiber current sensors 5 are mounted between two adjacent anode rods 3 and between the anode rod 3 and the column bus 1 or the crossover bus 6 for current measurement, the current of each anode can be measured accurately, and the measurement precision is accurate to be within 1%; the regional alumina feeding amount can be added as needed, and an anode state of the electrolytic cell is diagnosed, thereby achieving stable and efficient production of the electrolytic cell, significantly improving the current efficiency, reducing the energy consumption, and achieving further energy saving and emission reduction of the aluminum electrolytic cell.

By accurately detecting the independent anode current according to the present invention, the amount of alumina can be added as needed to avoid imbalance of anode current distribution and unbalanced alumina demand caused by conventional pole replacement operation. By accurately detecting the independent anode current, it is possible to obtain state information on each anode and each feeding point region, including alumina concentration, local pole pitch, and local fault. By accurately detecting the independent anode current, it is possible to predict the change trend and fault of local conditions, thereby achieving the health management of the whole aluminum electrolytic cell. By accurately detecting the independent anode current, higher current efficiency is achieved, and electrolysis can be carried out at a lower voltage. By accurately detecting the independent anode current, it is possible to predict and diagnose faults occurring to each anode/region. By accurately detecting the independent anode current, it is possible to timely determine local effects and perform processing, thereby eliminating anode effects and reducing greenhouse gas emissions.

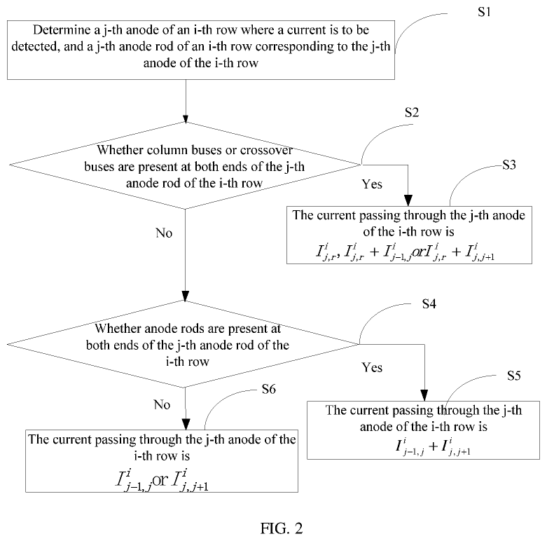

FIG. 2 is a flow chart of a method for measuring an anode current of an aluminum electrolytic cell according to an embodiment of the present invention. As shown in FIG. 2, the present invention further provides a method for measuring an anode current of an aluminum electrolytic cell, and the method includes:

Step S1: determine a j-th anode 2 of an i-th row where a current is to be detected, and a j-th anode rod 3 of an i-th row corresponding to the j-th anode 2 of the i-th row; where i is equal to A or B, and j is a positive integer which ranges from 2 to m/2.

Step S2: determine whether column buses 1 or crossover buses 6 are present at both ends of the j-th anode rod 3 of the i-th row, to obtain a first determining result.

Step S3: if the first determining result indicates that the column buses 1 or the crossover buses 6 are present, determine that the current passing through the j-th anode 2 of the i-th row is I_{j,r}ⁱ, I_{j,r}ⁱ+I_{j-1,j}ⁱ or I_{j,r}ⁱ+I_{j,j+1}ⁱ; where I_{j,r}ⁱ is a current detected by an optical fiber current sensor 5 between the column bus 1 or the crossover bus 6 and the j-th anode rod 3 of the i-th row, I_{j-1,j}ⁱ is a current detected by an optical fiber current sensor 5 between a (j−1)-th anode rod 3 of the i-th row and the j-th anode rod 3 of the i-th row; and I_{j,j+1}ⁱ is a current detected by an optical fiber current sensor 5 between the j-th anode rod 3 of the i-th row and a (j+1)-th anode rod 3 of the i-th row.

Step S4: if the first determining result indicates that the column buses 1 or the crossover buses 6 are not present, determine whether anode rods 3 are present at both ends of the j-th anode rod 3 of the i-th row, to obtain a second determining result.

Step S5: if the second determining result indicates that the anode rods 3 are present, determine that the current passing through the j-th anode 2 of the i-th row is I_{j-1,j}ⁱ+I_{j,j+1}ⁱ; where for example, the magnitude of a current passing through an anode 2A4 is determined by the magnitudes and directions of the current I_{3,4}^{A} measured by the optical fiber current sensor 5 between A3 and A4 and the current I_{4,5}^{A} measured by the optical fiber current sensor 5 between A4 and A5. During the calculation of the current passing through A4, when I_{3,4}^{A} and I_{4,5}^{A} are transmitted to the anode rod 3 corresponding to the anode 2A4, the direction is positive; and the direction is negative when I_{3,4}^{A} and I_{4,5}^{A} leave from the anode rod 3 corresponding to the anode 2A4. Therefore, the magnitude of the current of the anode 2A4 is I₄^{A}=I_{3,4}^{A}+I_{4,5}^{A}.

Step S6: determine, if the second determining result indicates that only one anode rod 3 is present, that the current passing through the j-th anode 2 of the i-th row is I_{j-1,j}ⁱ or I_{j,j+1}ⁱ.

Each step is described in detail below.

Step S3: if the first determining result indicates that the column buses 1 or the crossover buses 6 are present, determine that the current passing through the j-th anode 2 of the i-th row is I_{j,r}ⁱ, I_{j,r}ⁱ+I_{j-1,j}ⁱ or I_{j,r}ⁱ+I_{j,j+1}ⁱ specifically including:

Step S31: if the first determining result indicates that the column buses 1 or the crossover buses 6 are present, determine whether an anode rod 3 is present at the other end of the j-th anode rod 3 of the i-th row, to obtain a third determining result.

Step S32: if the third determining result indicates that the anode rod 3 is not present at the other end of the j-th anode rod 3 of the i-th row, determine that the current passing through the is j-th anode 2 of the i-th row I_{j,r}ⁱ.

Step S33: if the third determining result indicates that the anode rod 3 is present at the other end of the j-th anode rod 3 of the i-th row, determine whether the number thereof is the (j−1)-th of the i-th row, to obtain a fourth determining result.

Step S34: if the fourth determining result indicates that the number of the anode rod 3 at the other end of the j-th anode rod 3 of the i-th row is the (j−1)-th of the i-th row, determine that the current passing through the j-th anode 2 of the i-th row is I_{j,r}ⁱ+I_{j-1,j}ⁱ; where for example, the magnitude of a current passing through an anode 2B2 is determined by the magnitudes and directions of the current I_{1,2}^{B} measured by the optical fiber current sensor 5 between B1 and B2 and the current I_{2,r}^{B} measured by the optical fiber current sensor 5 between B2 and the crossover bus 6. During the calculation of the current passing through the anode 2B2, when I_{1,2}^{B} and I_{2,r}^{B} are transmitted to the anode rod 3 corresponding to the anode 2B2, the direction is positive; and the direction is negative when I_{1,2}^{B} and I_{2,r}^{B} leave from the anode rod 3 corresponding to the anode 2B2. Therefore, the magnitude of the current of the anode 2B2 is I₂^{B}=I_{1,2}^{B}+I_{2,r}^{B}.

Step S35: if the fourth determining result indicates that the number of the anode rod 3 at the other end of the j-th anode rod 3 of the i-th row is not the (j−1)-th of the i-th row, determine that the current passing through the j-th anode 2 of the i-th row is I_{j,r}ⁱ+I_{j,j+1}ⁱ; where for example, the magnitude of a current passing through an anode 2B3 is determined by the magnitudes and directions of the current I_{3,4}^{B} measured by the optical fiber current sensor 5 between B3 and B4 and the current I_{3,r}^{B} measured by the optical fiber current sensor 5 between B3 and the crossover bus 6. During the calculation of the current passing through the anode 2B3, when I_{3,4}^{B} and I_{3,r}^{B} are transmitted to the anode rod 3 corresponding to the anode 2B3, the direction is positive; and the direction is negative when I_{3,4}^{B} and I_{3,r}^{B} leave from the anode rod 3 corresponding to the anode 2B3. Therefore, the magnitude of the current of the anode 2B3 is I₃^{B}=I_{3,4}^{B}+I_{3,r}^{B}.

Step S6: if the second determining result indicates that only one anode rod 3 is present, determine that the current passing through the j-th anode 2 of the i-th row is I_{j-1,j}ⁱ or I_{j,j+1}ⁱ, specifically including:

Step S61: if the second determining result indicates that only one anode rod 3 is present, determine whether the number of the anode rod 3 is the (j−1)-th of the i-th row, to obtain a fifth determining result.

Step S62: if the fifth determining result indicates that the number of the anode rod 3 is the (j−1)-th of the i-th row, determine that the current passing through the j-th anode 2 of the i-th row is I_{j-1,j}ⁱ; where for example, the magnitude of a current passing through an anode 2A5 is determined by the magnitude and direction of the current I_{4,5}^{A} measured by the optical fiber current sensor 5 between A4 and A5. During the calculation of the current passing through the anode 2A5, when I_{4,5}^{A} is transmitted to the anode rod 3 corresponding to the anode 2A5, the direction is positive; and the direction is negative when I_{4,5}^{A} leaves from the anode rod 3 corresponding to the anode 2A5. Therefore, the magnitude of the current of the anode 2A5 is I₅^{A}=I_{4,5}^{A}.

Step S63: if the fifth determining result indicates that the number of the anode rod 3 is not the (j−1)-th of the i-th row, determine that the current passing through the j-th anode 2 of the i-th row is I_{j,j+1}ⁱ. For example, the magnitude of a current passing through an anode 2A1 is determined by the magnitude and direction of the current I_{1,2}^{A} measured by the optical fiber current sensor 5 between A1 and A2. During the calculation of the current passing through the anode 2A1, when I_{1,2}^{A} is transmitted to the anode rod 3 corresponding to the anode 2A1, the direction is positive; and the direction is negative when I_{1,2}^{A} leaves from the anode rod 3 corresponding to the anode 2A1. Therefore, the magnitude of the current of the anode 2A1 is I₁^{A}=I_{1,2}^{A}.

Each embodiment of the present specification is described in a progressive manner, each embodiment focuses on the difference from other embodiments, and the same and similar parts between the embodiments may refer to each other. For a system disclosed in the embodiments, since it corresponds to the method disclosed in the embodiments, the description is relatively simple, and reference can be made to the method description.

Several examples are used for illustration of the principles and implementation methods of the present invention. The description of the embodiments is used to help illustrate the method and its core principles of the present invention. In addition, those skilled in the art can make various modifications in terms of specific embodiments and scope of application in accordance with the teachings of the present invention. In conclusion, the content of this specification shall not be construed as a limitation to the present invention.

What is claimed is:

1. A system for measuring an anode current of an aluminum electrolytic cell, comprising a plurality of electrolytic cell units;
wherein the electrolytic cell units each comprise: a column bus, two horizontal buses, m anodes, m anode rods, one or a pair of crossover buses, and a plurality of optical fiber current sensors;
the m anode rods and the m anodes are divided into two rows A and B, one end of each of the anode rods of each row is respectively in lap joint with the horizontal bus, the other end of each of the anode rods of each row is respectively connected to the anode of each row, and each of the anodes is in one-to-one correspondence with the anode rod; the crossover buses are disposed on one or two sides of a feeding port, the two horizontal buses are connected through the crossover buses, and one end of the column bus is connected to the first horizontal bus;
when one side of the anode rod is adjacent to another anode rod, the horizontal bus between the two anode rods is provided with one of the optical fiber current sensors;
when any side of the anode rod is adjacent to the column bus or the crossover bus, the horizontal bus between the anode rod and the column bus or the crossover bus is provided with one of the optical fiber current sensors; and
when any side of the anode rod is neither adjacent to the anode rod nor adjacent to the column bus or the crossover bus, the horizontal bus on this side does not need to be provided with the optical fiber current sensor.

2. The system according to claim 1, further comprising:
an optical fiber protecting tube, configured to, through a polarization maintaining optical fiber concentrated in the optical fiber protecting tube, transmit current information detected by the optical fiber current sensors to a measuring box for analysis and processing.

3. A method for measuring an anode current of an aluminum electrolytic cell, wherein the method is applied to the system according to claim 1, and the method comprises:
determining a j-th anode of an i-th row wherein a current is to be detected, and a j-th anode rod of an i-th row corresponding to the j-th anode of the i-th row; wherein i is equal to A or B, and j is a positive integer which ranges from 2 to m/2;
determining whether column buses or crossover buses are present at both ends of the j-th anode rod of the i-th row, to obtain a first determining result;
if the first determining result indicates that the column buses or the crossover buses are present, determining that the current passing through the j-th anode of the i-th row is I_{j,r}ⁱ, I_{j,r}ⁱ+I_{j-1,j}ⁱ or I_{j,r}ⁱ+I_{j,j+1}ⁱ; wherein I_{j,r}ⁱ is a current detected by an optical fiber current sensor between the column bus or the crossover bus and the j-th anode rod of the i-th row, I_{j-1,j}ⁱ is a current detected by an optical fiber current sensor between a (j−1)-th anode rod of the i-th row and the j-th anode rod of the i-th row; and I_{j,j+1}ⁱ is a current detected by an optical fiber current sensor between the j-th anode rod of the i-th row and a (j+1)-th anode rod of the i-th row;
if the first determining result indicates that the column buses or the crossover buses are not present, determining whether anode rods are present at both ends of the j-th anode rod of the i-th row, to obtain a second determining result;
if the second determining result indicates that the anode rods are present, determining that the current passing through the j-th anode of the i-th row is I_{j-1,j}ⁱ+I_{j,j+1}ⁱ;
if the second determining result indicates that only one anode rod is present, determining that the current passing through the j-th anode of the i-th row is I_{j-1,j}ⁱ or I_{j,j+1}ⁱ.

4. A method for measuring an anode current of an aluminum electrolytic cell, wherein the method is applied to the system according to claim 2, and the method comprises:
determining a j-th anode of an i-th row wherein a current is to be detected, and a j-th anode rod of an i-th row corresponding to the j-th anode of the i-th row; wherein i is equal to A or B, and j is a positive integer which ranges from 2 to m/2;
determining whether column buses or crossover buses are present at both ends of the j-th anode rod of the i-th row, to obtain a first determining result;
if the first determining result indicates that the column buses or the crossover buses are present, determining that the current passing through the j-th anode of the i-th row is I_{j,r}ⁱ, I_{j,r}ⁱ+I_{j-1,j}ⁱ or I_{j,r}ⁱ+I_{j,j+1}ⁱ; wherein I_{j,r}ⁱ is a current detected by an optical fiber current sensor between the column bus or the crossover bus and the j-th anode rod of the i-th row, I_{j-1,j}ⁱ is a current detected by an optical fiber current sensor between a (j−1)-th anode rod of the i-th row and the j-th anode rod of the i-th row; and I_{j,j+1}ⁱ is a current detected by an optical fiber current sensor between the j-th anode rod of the i-th row and a (j+1)-th anode rod of the i-th row;
if the first determining result indicates that the column buses or the crossover buses are not present, determining whether anode rods are present at both ends of the j-th anode rod of the i-th row, to obtain a second determining result;
if the second determining result indicates that the anode rods are present, determining that the current passing through the j-th anode of the i-th row is I_{j-1,j}ⁱ+I_{j,j+1}ⁱ;
if the second determining result indicates that only one anode rod is present, determining that the current passing through the j-th anode of the i-th row is I_{j-1,j}ⁱ or I_{j,j+1}ⁱ.

5. The method according to claim 3, wherein the determining, if the first determining result indicates that the column buses or the crossover buses are present, that the current passing through the j-th anode of the i-th row is I_{j,r}ⁱ, I_{j,r}ⁱ+I_{j-1,j}ⁱ or I_{j,r}ⁱ+I_{j,j+1}ⁱ specifically comprises:
if the first determining result indicates that the column buses or the crossover buses are present, determining whether an anode rod is present at the other end of the j-th anode rod of the i-th row, to obtain a third determining result;
if the third determining result indicates that the anode rod is not present at the other end of the j-th anode rod of the i-th row, determining that the current passing through the j-th anode of the i-th row is I_{j,r}ⁱ;
if the third determining result indicates that the anode rod is present at the other end of the j-th anode rod of the i-th row, determining whether the number thereof is the (j−1)-th of the i-th row, to obtain a fourth determining result;
if the fourth determining result indicates that the number of the anode rod at the other end of the j-th anode rod of the i-th row is the (j−1)-th of the i-th row, determining that the current passing through the j-th anode of the i-th row is I_{j,r}ⁱ+I_{j-1,j}ⁱ; and
if the fourth determining result indicates that the number of the anode rod at the other end of the j-th anode rod of the i-th row is not the (j−1)-th of the i-th row, determining that the current passing through the j-th anode of the i-th row is I_{j,r}ⁱ+I_{j,j+1}ⁱ.

6. The method according to claim 4, wherein the determining, if the first determining result indicates that the column buses or the crossover buses are present, that the current passing through the j-th anode of the i-th row is I_{j,r}ⁱ, I_{j,r}ⁱ+I_{j-1,j}ⁱ or I_{j,r}ⁱ+I_{j,j+1}ⁱ specifically comprises:
if the first determining result indicates that the column buses or the crossover buses are present, determining whether an anode rod is present at the other end of the j-th anode rod of the i-th row, to obtain a third determining result;
if the third determining result indicates that the anode rod is not present at the other end of the j-th anode rod of the i-th row, determining that the current passing through the j-th anode of the i-th row is I_{j,r}ⁱ;
if the third determining result indicates that the anode rod is present at the other end of the j-th anode rod of the i-th row, determining whether the number thereof is the (j−1)-th of the i-th row, to obtain a fourth determining result;
if the fourth determining result indicates that the number of the anode rod at the other end of the j-th anode rod of the i-th row is the (j−1)-th of the i-th row, determining that the current passing through the j-th anode of the i-th row is I_{j,r}ⁱ+I_{j-1,j}ⁱ; and
if the fourth determining result indicates that the number of the anode rod at the other end of the j-th anode rod of the i-th row is not the (j−1)-th of the i-th row, determining that the current passing through the j-th anode of the i-th row is I_{j,r}ⁱ+I_{j,j+1}ⁱ.

7. The method according to claim 3, wherein the determining, if the second determining result indicates that only one anode rod is present, that the current passing through the j-th anode of the i-th row is I_{j-1,j}ⁱ or I_{j,j+1}ⁱ specifically comprises:
if the second determining result indicates that only one anode rod is present, determining whether the number of the anode rod is the (j−1)-th of the i-th row, to obtain a fifth determining result;
if the fifth determining result indicates that the number of the anode rod is the (j−1)-th of the i-th row, determining that the current passing through the j-th anode of the i-th row is I_{j-1,j}ⁱ; and
if the fifth determining result indicates that the number of the anode rod is not the (j−1)-th of the i-th row, determining that the current passing through the j-th anode of the i-th row is I_{j,j+1}ⁱ.

8. The method according to claim 4, wherein the determining, if the second determining result indicates that only one anode rod is present, that the current passing through the j-th anode of the i-th row is I_{j-1,j}ⁱ or I_{j,j+1}ⁱ specifically comprises:
if the second determining result indicates that only one anode rod is present, determining whether the number of the anode rod is the (j−1)-th of the i-th row, to obtain a fifth determining result;
if the fifth determining result indicates that the number of the anode rod is the (j−1)-th of the i-th row, determining that the current passing through the j-th anode of the i-th row is I_{j-1,j}ⁱ; and
if the fifth determining result indicates that the number of the anode rod is not the (j−1)-th of the i-th row, determining that the current passing through the j-th anode of the i-th row is I_{j,j+1}ⁱ.

9. The method according to claim 3, wherein for the j-th anode rod of the i-th row, a current passing in the direction towards the anode rod is positive, and a current in the direction away from the anode rod is negative.

10. The method according to claim 4, wherein for the j-th anode rod of the i-th row, a current passing in the direction towards the anode rod is positive, and a current in the direction away from the anode rod is negative.
